(19) United States
(12) Patent Application Publication
(10) Pub. No.: US 2026/0246199 A1
(43) Pub. Date: Aug. 20, 2026

(54) POWER CONNECTOR WITH IMPROVED HEAT DISSIPATION PERFORMANCE

(71) Applicant: FOXCONN INTERCONNECT TECHNOLOGY LIMITED, Grand Cayman (KY)

(72) Inventor: YUNG-CHIH HUNG, New Taipei (TW)

(21) Appl. No.: 19/532,619

(22) Filed: Feb. 6, 2026

(30) Foreign Application Priority Data
Feb. 17, 2025 (CN) 202510173807.3

(51) Int. Cl. H01R 13/533; H01R 13/11; H01R 13/50; H01R 13/66; H01R 25/14; H05K 7/20

(52) U.S. Cl. CPC H01R 13/533; H01R 13/11; H01R 13/50; H01R 13/6675; H01R 25/142; H05K 7/20418; H05K 7/2049

(57) ABSTRACT

A power connector includes: an insulating housing including a mating slot extending forward in a mating direction; two power assemblies disposed on opposite sides of the mating slot respectively in a first direction perpendicular to the mating direction, each of the power assemblies having contacting portions protruding into the mating slot in the first direction and a power extension extending rearward out of the insulating housing; and two heat dissipation devices; wherein each of the heat dissipation devices is attached to a surface of the corresponding power assembly and extends outside the insulating housing.

### BACKGROUND OF THE INVENTION

### 1. Field of the Invention

The present invention relates to a power connector for transmitting high current.

### 2. Description of Related Arts

U.S. Patent Application Publication No. 2025/0226627 discloses a busbar power connector including a housing and two sets of connector assemblies. The housing includes a main portion and two plugging portions. The main portion has a first opening. The plugging portions are configured to plug into the jacks of a receptacle. The two sets of connector assemblies may be identical and symmetrically disposed in the housing. The connector assembly includes a terminal module, a cable module, and a heat sink. The terminal module includes a conductive plate accommodated in the main portion and terminals extending to the plugging portion. The cable module extends out of the housing from the first opening. The heat sink is coupled to a conductive plate. The terminal module uses the conductive plate to be thermally coupled to the heat sink so the connector assembly can effectively solve the heat dissipation problem of the terminal module. However, since the heat sink is disposed inside the main portion, it can only exchange heat with the outside through the first opening, resulting in poor heat dissipation performance.

An improved power connector is desired.

### SUMMARY OF THE INVENTION

An object of the present invention is to provide a power connector that can improve the issue of temperature rise.

To achieve the above-mentioned object, a power connector includes: an insulating housing including a mating slot extending forward in a mating direction; two power assemblies disposed on opposite sides of the mating slot respectively in a first direction perpendicular to the mating direction, each of the power assemblies having contacting portions protruding into the mating slot in the first direction and a power extension extending rearward out of the insulating housing; and two heat dissipation devices; wherein each of the heat dissipation devices is attached to a surface of the corresponding power assembly and extends outside the insulating housing.

Other advantages and novel features of the invention will become more apparent from the following detailed description of the present embodiment when taken in conjunction with the accompanying drawings.

### BRIEF DESCRIPTION OF DRAWINGS

FIG. 1 is a schematic plan view of a power connector and a bus bar device before mating according to an embodiment of the present application.

FIG. 2 is a cross-sectional view of the power connector taken along a line A-A in FIG. 1.

FIG. 3 is a front and top perspective view of the power connector in FIG. 1 mounted on a panel of a device.

FIG. 4 is a front and bottom perspective view of the power connector in FIG. 3, in which the panel is removed.

FIG. 5 is an exploded perspective view of the power connector in FIG. 4, in which one grounding member is disassembled.

FIG. 6 is an exploded perspective view of the power connector in FIG. 4, in which one heat dissipation module is disassembled.

FIG. 7 is an exploded perspective view of FIG. 6 from another angle.

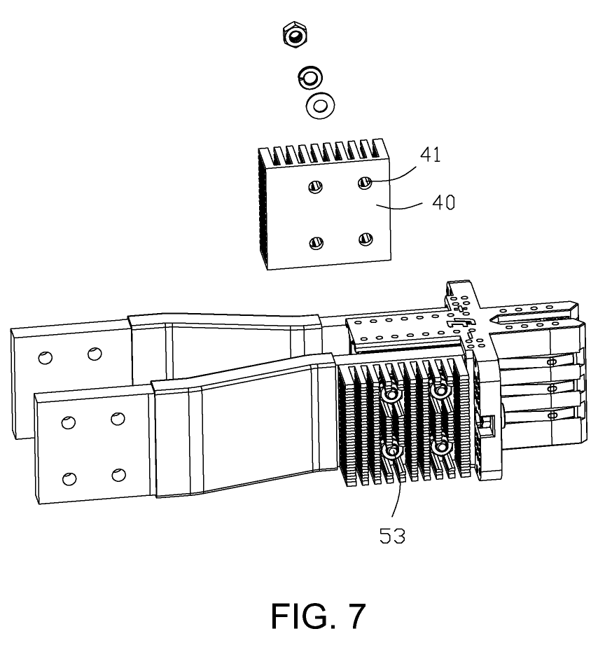

FIG. 8 is a perspective view of an insulating housing in FIG. 6.

FIG. 9 is a perspective view of two power assemblies and two heat dissipation devices in FIG. 6.

FIG. 10 is a perspective view of one power assembly and the heat dissipation device in FIG. 9.

FIG. 11 is a perspective view of a power terminal in FIG. 9.

FIG. 12 is a perspective view of a first piece in FIG. 11.

FIG. 13 is a perspective view of a second piece in FIG. 11.

FIG. 14 is a perspective view of a third piece in FIG. 11.

FIG. 15 is a perspective view of a fourth piece in FIG. 11.

### DETAILED DESCRIPTION OF THE PREFERRED EMBODIMENT

Reference will now be made to the drawing figures to describe the preferred embodiment of the present invention in detail.

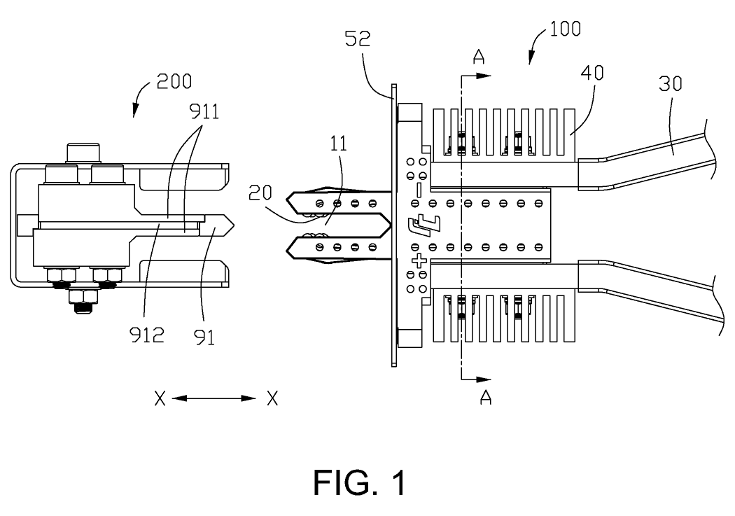

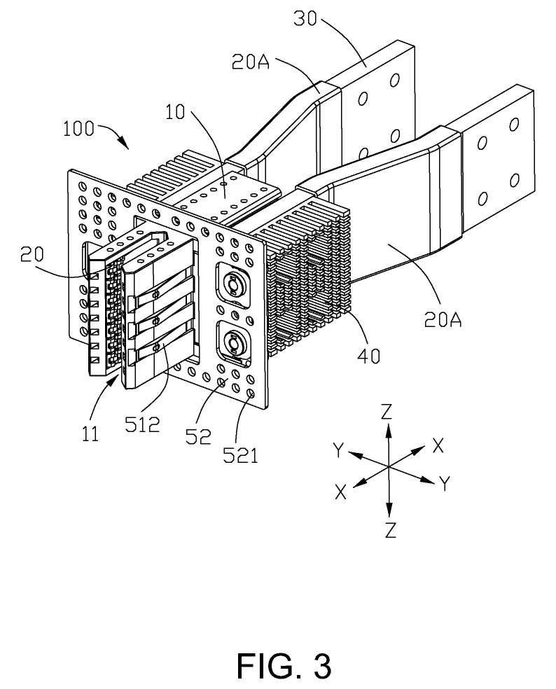

Referring to FIGS. 1 and 3, the power connector 100 is used to mate with a DC power distribution bus, or what is known in the industry as a bus bar. The power connector 100 is used for mating with a bus bar device 200 to transmit high current in this embodiment. The bus bar device 200 includes a plug 91, which has a positive conductor/ bus bar 911, a negative conductor/ bus bar 911, and an insulating strip 912 that supports the positive and negative conductors. The positive and negative conductors are respectively embedded in two opposite side surfaces of the insulating strip 912. The power connector 100 can be mounted on a circuit board or an electronic device. When the plug 91 is inserted into a mating slot 11 of the power connector 100, the power terminals 20 located on both sides of the mating slot 11 contact the positive and negative conductors respectively, and the current is transmitted to other electronic components via the power transmitting member at a rear ends of the power connector 100, thereby enabling the transmission of high current. The mating slot 11 not only extends forward, but also penetrates in a vertical direction, facilitating the elongated plug 91 to pass through.

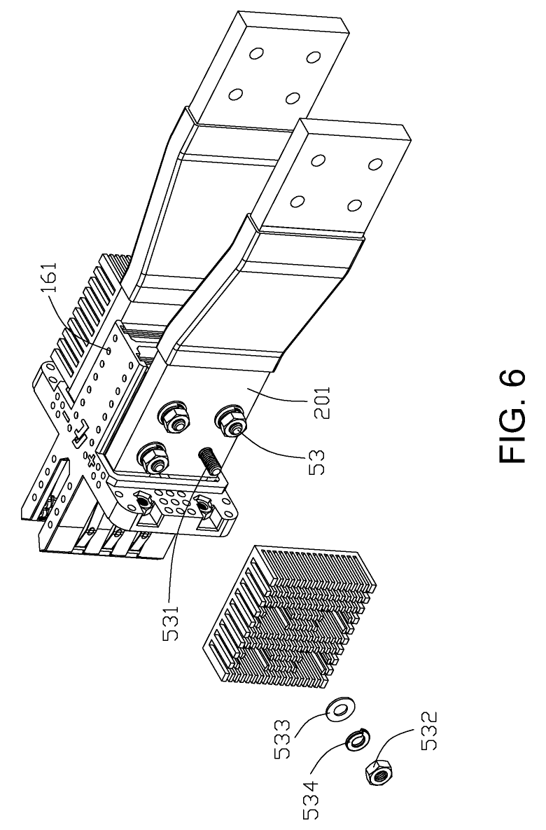

Referring to FIGS. 3-6, the power connector 100 includes an insulating housing 10, two power assemblies 20A, and two heat dissipation devices 40. The insulating housing has the mating slot 11 extending forward in a mating direction. The two power assemblies are respectively disposed on the opposite sides of the mating slot 11 in a first direction Y-Y. Each of the power assemblies 20A includes a contacting portion 21 protruding into the mating slot 11 in the first direction and a power extension 30 extending rearward out of the insulating housing 10. Each heat dissipation device 40 is attached to a surface 201 of the corresponding power assembly 20A directly and extends outside the insulating housing 10, as shown in FIG. 6. The two contacting portions 21 are respectively located on the lateral sides of the mating slot 11. The heat dissipation device 40 is attached to the surface 201 of the power assembly 20A directly, allowing the heat generated by the power assembly to be dissipated quickly, thereby achieving rapid heat dissipation and preventing excessive temperature rise of the power assembly, which improves the temperature rise issue under high current. The insulating housing 10 further has a plurality of heat dissipation holes 16 to increase heat dissipation capacity. A pair of grounding members 51 is disposed at a front end of the insulating housing 10. A panel 52 is mounted at a front end of the insulating housing 10. The panel 52 has a plurality of heat dissipation holes 521 to further enhance heat dissipation capacity.

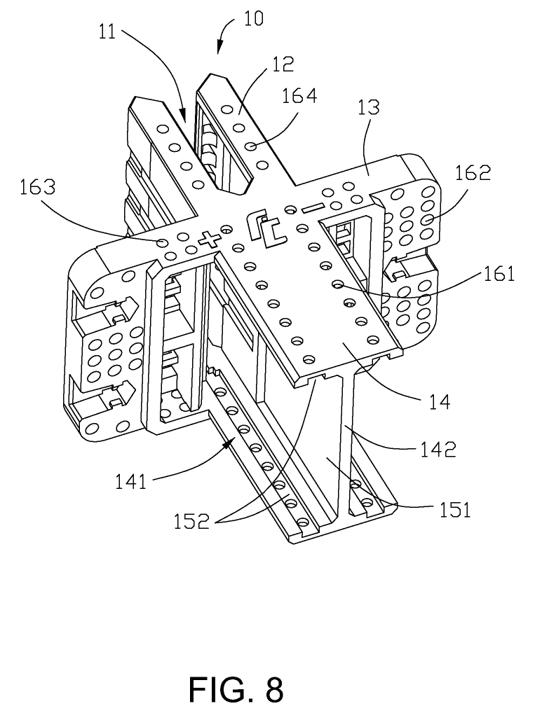

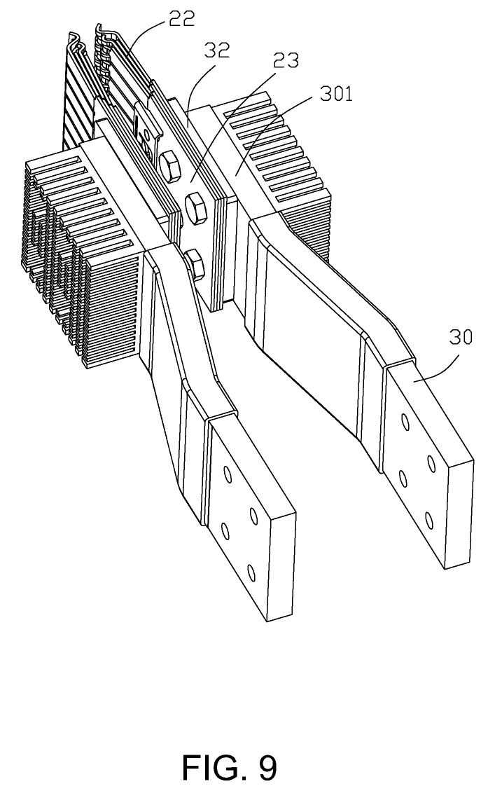

Referring to FIGS. 8 and 9, the insulating housing 10 includes a base portion 13, a mating portion 12 extending forward from the base portion, and a mounting portion 14 extending rearward from the base portion. The mating slot 11 is disposed in the mating portion 12. The mounting portion 14 has two openings 141 at opposite outsides thereof in the first direction. At least part of the power assembly 20A is exposed in the opening 141. The heat dissipation device 40 is attached to the surface of the power assembly 20A corresponding to the opening 141. The insulating housing 10 has two receiving cavities 151 located behind the mating slot 11. The two receiving cavities 151 are insulated and separated from each other with a partition wall 142. The partition wall 142 corresponds to the mating slot 11 in the mating direction. The partition wall 142 insulates and separates the two power assemblies 20A. Each receiving cavity 151 has a fixing groove 152 on each of two opposite insides thereof in the second direction. The fixing grooves 152 are located on a top and a lower of the receiving cavity 151. The power assembly 20A passes through and is housed in the receiving cavity 151. Both sides of the power assembly interfere with and are fixed by the fixing grooves 152. Each receiving cavity 151 opens outward in the first direction. In this embodiment, the opening 141 extends forward to the base portion 13 and penetrates rearward through the mounting portion 14. The opening 141 also extends laterally to approach an upper surface and a lower surface of the mounting portion 14. The receiving cavities 151 are completely open in the first direction, which not only increases the heat dissipation space but also provides space for exposing the power assembly 20A, thereby facilitating the installation of the heat dissipation device 40. The heat dissipation device 40 is completely attached to the surface 201 of the power assembly to achieve maximum heat transfer.

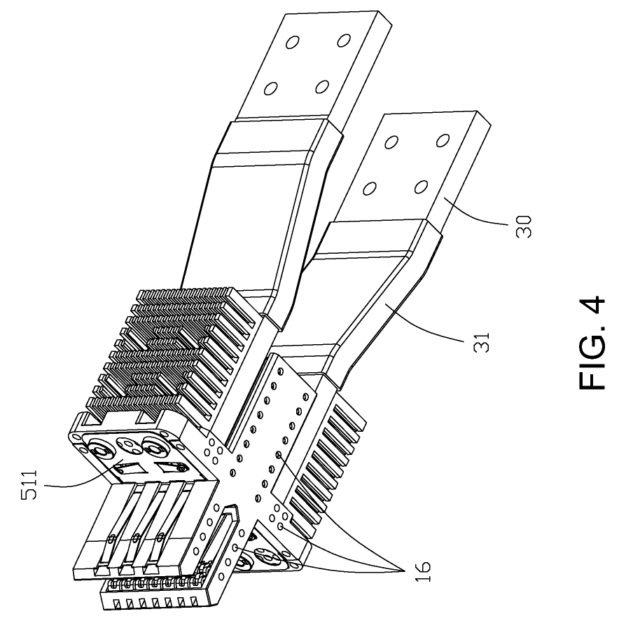

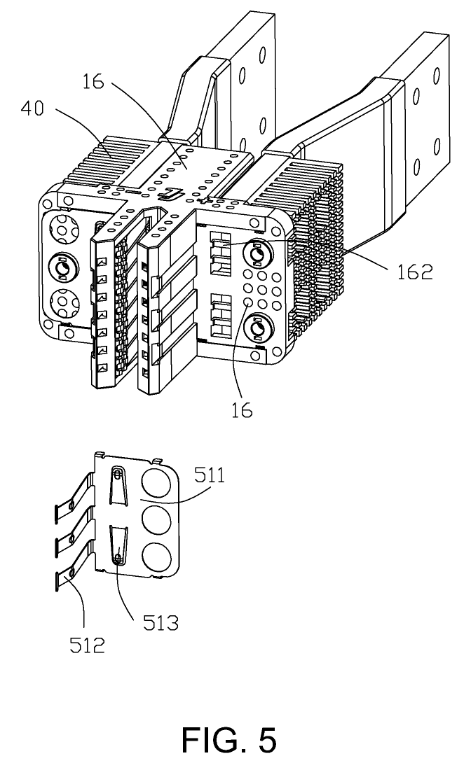

Referring to FIGS. 4 to 5, the mating portion 12 has a plurality of heat dissipation holes 16, which can conduct the heat generated by the contacting portion 21 to the outside through the heat dissipation holes 16 quickly. The base portion 13 and the mounting portion 14 has a plurality of heat dissipation holes 16,which can conduct the heat generated by other parts of the power assembly 20A outward. The heat dissipation holes, i.e., first heat dissipation holes 161 located in the mounting portion 14 are in communication with the fixing grooves 152 in a second direction Z-Z, thereby conducting the heat generated at the sides of the power assembly 20A outward. The mating direction, the first direction and the second direction are perpendicular to each other. Since the mating portion 12 cannot accommodate a heat dissipation device, the opening 141 can expose parts of the power assembly 20A, and the heat dissipation device 40 can be installed at the opening. In this way, the heat dissipation device 40 can be as close as possible to the contacting portion 21 to conduct away the heat generated by the area with the fastest temperature rise in a timely manner.

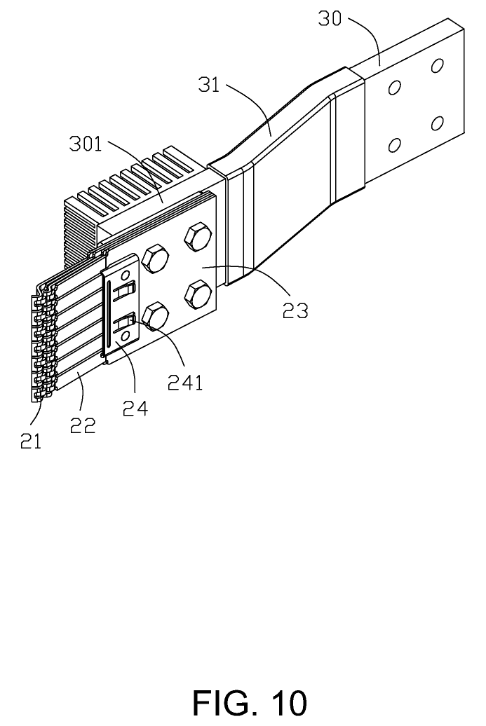

As shown in FIGS. 9 to 10, in this embodiment, each power assembly 20A includes a power terminal 20 and a power extension 30. The power terminal 20 includes a plate portion 23 and a plurality of elastic arms 22 extending forward from the plate portion. The contacting portion 21 is disposed at a front end of the elastic arm 22. The plate portions 23 are retained with the insulating housing 10 and are exposed in the openings 141. A front end 301 of the power extension 30 is attached to an outside of the opening 141 and connected to the plate portion 23. The heat dissipation device 40 is attached to an outer surface of the power extension 30 corresponding to the plate portion 23. In a specific embodiment, the power extension 30 is an elongated conductive plate, i.e., bus bar. A front end 301 of the power extension attached to the plate portion 23 directly, or another conductive plate 32 is clamped between the front end of the power extension 30 and the plate portion 23. The elongated conductive plate 32 may be made of copper or aluminum. The elongated conductive plate 32 is covered with an insulating sleeve 31 for protection. In other embodiments, the power extension 30 may be a cable, of which a front end is flattened by ultrasonic welding. A flat surface of the cable can be used for attaching the heat dissipation device 40. In other embodiments, if the power extension 30 is attached to an inner surface of the plate portion 23, then the heat dissipation device 40 is attached to an outer surface of the plate portion 23, thereby achieving rapid heat dissipation.

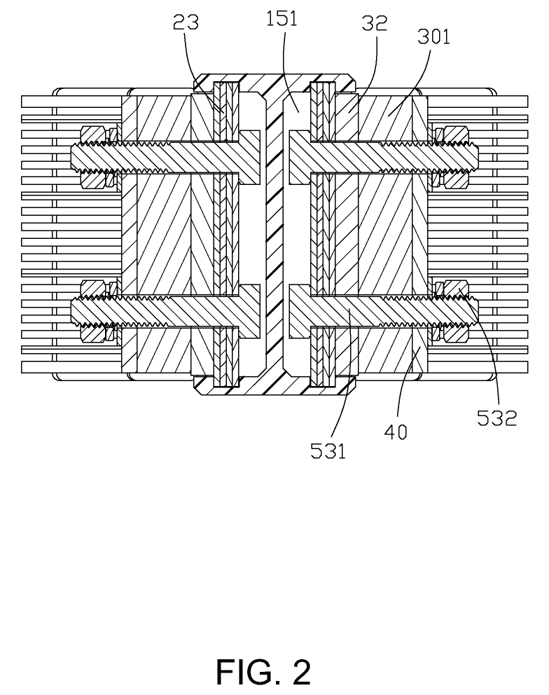

As shown in FIGS. 2 and 5-6, in this embodiment, the front end 301 of the power extension 30 is fixed to the outer surface of the plate portion 23 of the power terminal 20, and the heat dissipation device 40 is attached to the outer surface of the power extension 30. The plate portion 23 and the front end 301 of the power extension are fastened together by a plurality of nut assemblies 53. A reinforcing member 24 is fixed to the inner surface of the plate portion 23, thereby forming an integral structure, which is inserted forward into the receiving cavity 151 from the rear. Two side edges of the plate portion 23 are fixed within the fixing grooves 152, thus fixing the power assembly 20A and the heat dissipation device 40 to the insulating housing 10. A plurality of latching tabs 241 of the reinforcing member 24 are latched inside the insulating housing 10 to prevent the power assembly 20A from disengaging rearward. In this embodiment, four nut assemblies 53 are used to fix the heat dissipation device 40 to the power assembly 20A. For each nut assembly 53, a bolt 531 passes through the through hole 41 of the power assembly and the heat dissipation device 40, and is secured by a nut 532. A washer 533 and an elastic ring 534 are also sleeved between the nut and the surface 201 of the power assembly.

As shown in FIGS. 4 to 5, the base portion 13 protrudes laterally relative to both the mating portion 12 and the mounting portion 14 in the first direction and the second direction, thereby forming a flange structure. Each grounding member 51 includes a base plate 511 and a plurality of elastic extension arms 512 extending forward from the base plate 511. The base plate 511 is fixed to a front end surface of the base portion 13. The plurality of elastic extension arms 512 is disposed on a lateral outside of the mating portion 13. Referring to FIG. 8, a plurality of second heat dissipation holes 162 run through the base portion 13 in the mating direction. The base plate 511 has spring tabs 513 corresponding to the second heat dissipation holes 162 of the base portion 13. A plurality of third heat dissipation holes 163 run through the base portion 13 in the second direction. A plurality of fourth heat dissipation holes 164 run through an upper side and a lower side of the mating portion 12. The panel 52 is mounted on the front end surface of the base portion 13. The panel 52 has a plurality of heat dissipation holes 521.

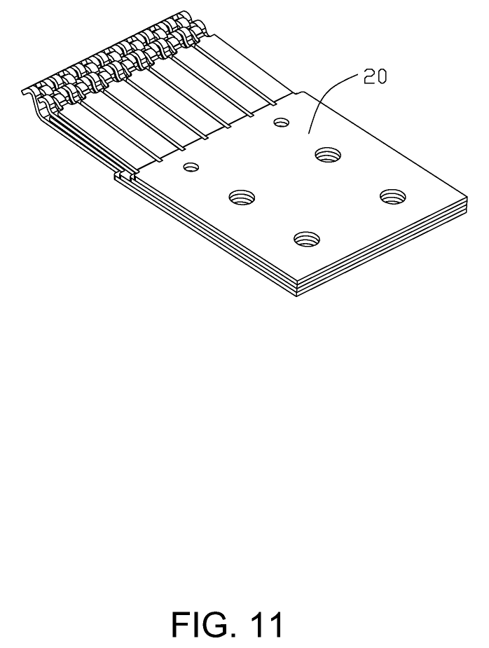

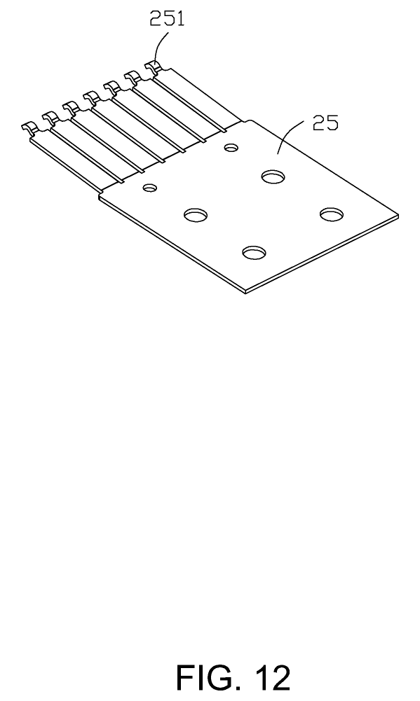

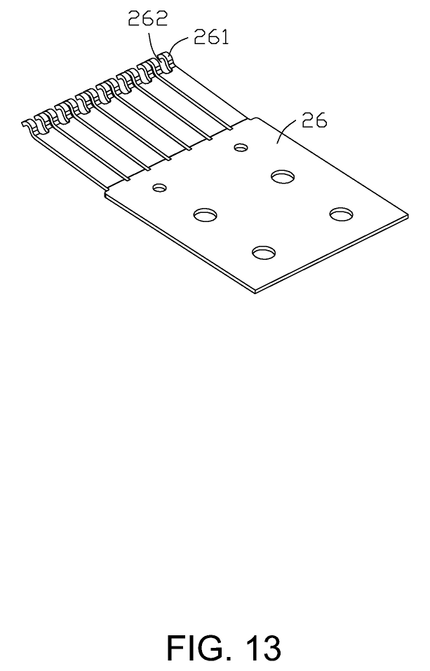

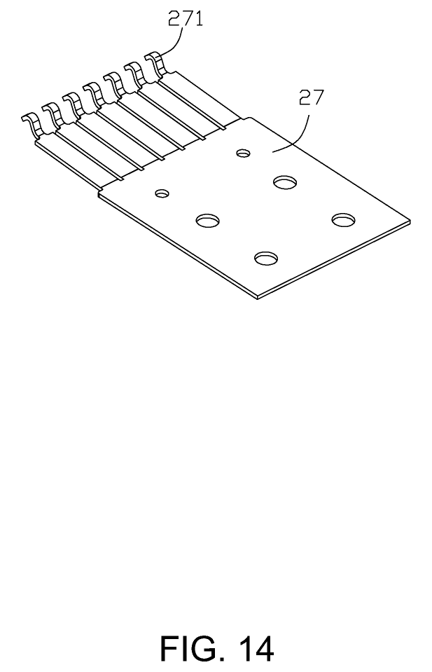

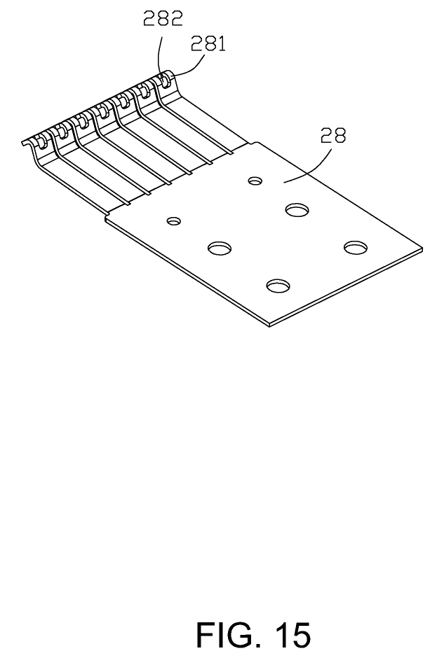

Referring to FIGS. 11 to 15, in this embodiment, each power terminal 20 includes a first piece 25, a second piece 26, a third piece 27, and a fourth piece 28, which are stacked in the first direction. A front end of the contacting portion 251 of the first piece is received within a notch 262 formed in the contacting portion 261 at a front end of the second piece. A front end of the contacting portion 271 of the third piece is received within a notch 282 formed in the contacting portion 281 at the front end of the fourth piece. The notches 262 and 282 provide deformation space for the contacting portions of the first and third pieces. Each contacting portion of the second piece and the fourth piece is divided into two parts by the notch, thus forming a parallel connection, thereby providing sufficient conductors for high current to pass through.

The above-mentioned embodiments are only preferred embodiments of the present invention, and should not limit the scope of the present invention, any simple equivalent changes and modifications made according to the claims of the present invention and the contents of the description should still belong to the present invention.

1. A power connector comprising:
an insulating housing comprising a mating slot extending forward in a mating direction;
two power assemblies disposed on opposite sides of the mating slot respectively in a first direction perpendicular to the mating direction, each of the power assemblies having contacting portions protruding into the mating slot in the first direction and a power extension extending rearward out of the insulating housing; and
two heat dissipation devices;
wherein each of the heat dissipation devices is attached to a surface of the corresponding power assembly and extends outside the insulating housing.

2. The power connector as claimed in claim 1, wherein:
the insulating housing comprises a base portion, a mating portion extending forward from the base portion, and a mounting portion extending rearward from the base portion;
the mating slot is disposed in the mating portion; and
the mounting portion has openings opening outwards in the first direction, each power assembly is at least partly exposed to the openings, heat dissipation devices correspond to the openings.

3. The power connector as claimed in claim 2, wherein each of the openings extend forward to the base portion and penetrates rearward through the mounting portion.

4. The power connector as claimed in claim 2, wherein the base portion and the mounting portion have a plurality of heat dissipation holes.

5. The power connector as claimed in claim 4, wherein the insulating housing has a plurality of the heat dissipation holes running through the mounting portion in a second direction perpendicular to the mating direction and the first direction.

6. The power connector as claimed in claim 4, wherein the insulating housing has a plurality of heat dissipation holes running through the base portion in the mating direction, and a plurality of heat dissipation holes running through the base portion in a second direction perpendicular to the mating direction and the first direction.

7. The power connector as claimed in claim 6, further comprising two grounding members, wherein each of the grounding members comprises a base plate and a plurality of elastic extension arms extending forward from the base plate, the base plate is fixed to a front surface of the base portion, the plurality of elastic extension arms are disposed on an outside of the mating portion in the first direction, and the base plate has spring tabs corresponding to the heat dissipation holes.

8. The power connector as claimed in claim 2, wherein the mating portion has a plurality of heat dissipation holes.

9. The power connector as claimed in claim 8, wherein the insulating housing has a plurality of heat dissipation holes running through the mating portion in the second direction.

10. The power connector as claimed in claim 2, wherein each of the power assemblies comprises a power terminal and the power extension, the power terminal comprises a plate portion and a plurality of elastic arms extending forward from the plate portion, the elastic arms have the contacting portion, the plate portion is exposed in the opening, a front end of the power extension is attached to an outside of the plate portion, and the heat dissipation device is attached to an outside of front end of the power extension.

11. The power connector as claimed in claim 10, wherein the power extension is an elongated conductive plate.

12. The power connector as claimed in claim 10, wherein a panel is mounted at a front end of the base portion, and the panel has a plurality of heat dissipation holes opening in the mating direction.

13. The power connector as claimed in claim 1, wherein the insulating housing comprises two receiving cavities located behind the mating slot in the mating direction and separated from each other, each of the receiving cavities has fixing grooves, each of the power assemblies is housed in the receiving cavity, and opposite sides of each power assembly are fixed within the corresponding fixing grooves.

14. The power connector as claimed in claim 13, wherein the insulating housing has a plurality of heat dissipation holes opening through the corresponding fixing grooves.

15. A power connector comprising:
an insulating housing having a mating slot opening forward in a mating direction and a mounting portion extending rearward; and
two power assemblies disposed on opposite sides of the mating slot respectively in a first direction perpendicular to the mating direction;
wherein the mounting portion has two openings opening outwards in the first direction and a plurality of first heat dissipation holes opening in a second direction orthogonal to the mating direction and the first direction to at least partially expose the power assemblies.

16. The power connector as claimed in claim 15, wherein each of the power assemblies comprises a power terminal and a power extension, the power terminal comprises contacting portions protruding into the mating direction and a plate portion retained in the mounting portion, a front end of the power extension is attached to the plate portion, and the first heat dissipation holes are aligned with the plate portion in the second direction. .

17. The power connector as claimed in claim 16, wherein the front end of the power extension is located at an outside of the mounting portion and is attached to the plate portion through the opening.

18. The power connector as claimed in claim 16, wherein the mounting portion comprises a partition wall corresponding to the mating slot, and the partition wall insulates and separates the two power assemblies.

19. The power connector as claimed in claim 16, wherein the insulating housing
comprises a base portion from which a mating portion and the mounting portion extending, the mating slot is disposed in the mating portion, and the base portion has a plurality of second heat dissipation holes opening in the mating direction and a plurality of third heat dissipation holes opening in the second direction.

20. The power connector as claimed in claim 19, wherein the mating portion has a plurality of fourth heat dissipation holes opening in the second direction.
